(19) United States
(12) Patent Application Publication
(10) Pub. No.: US 2008/0230382 A1
(43) Pub. Date: Sep. 25, 2008

(54) SPUTTER CATHODE ASSEMBLY AND SPUTTER COATING DEVICE

(75) Inventor: Harald Gaertner, Schoeneck (DE)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Applied Materials, Inc., Santa Clara, CA (US)

(21) Appl. No.: 12/051,155

(22) Filed: Mar. 19, 2008

Related U.S. Application Data
(60) Provisional application No. 60/896,140, filed on Mar. 21, 2007.

(30) Foreign Application Priority Data
Mar. 21, 2007 (EP) 07104546.2

(51) Int. Cl. C23C 14/35

(52) U.S. Cl. 204/298.16

(57) ABSTRACT

A magnetron cathode assembly of the present invention comprises a drive shaft, one end being connected with a cathode or target assembly in the interior space of a vacuum chamber. A housing is rigidly mounted to the wall of a coating chamber of a sputter coating device by a flange. Between the housing and the drive shaft, a combined axial and radial bearing, such as a cross roller bearing, is arranged. The bearing supports the shaft rotatably relative to the housing. By providing the combined axial and radial bearing, the installation space of the assembly may be reduced.

### CROSS-REFERENCES TO RELATED APPLICATIONS

This application claims priority to U.S. Provisional Patent Application No. 60/896,140, entitled “Sputter Cathode Assembly and Sputter Coating Device,” filed Mar. 21, 2007 which is incorporated by reference herein for all purposes.

This application also claims the benefit of European Patent Application No. EP 07104546.2, entitled “Sputter Cathode Assembly and Sputter Coating Device,” filed Mar. 21, 2007 which is incorporated by reference herein for all purposes.

### BACKGROUND OF THE INVENTION

The present invention relates to a sputter cathode assembly, particularly to a magnetron sputter cathode assembly, comprising at least one bearing system for rotatably supporting a rotatable cathode or target structure. Furthermore, the invention relates to a sputter coating device.

Sputtering is commonly used as a coating technology for coating substrates, e.g. large area glass substrates, within a vacuum chamber. In this sputtering process, plasma is generated within an enclosed reaction chamber for depositing a thin film of target material on a stationary substrate or on a substrate that moves through the chamber and passes the target.

In order to increase the sputtering rate, magnetron sputtering has been developed which involves configuring an external magnet field to trap electrons in a region above the surface of the target/cathode. Thus an increased particle density may be generated. Furthermore, particles are sputtered from a substantially cylindrical rotatable target to improve the material usage of the target. Rotatable target tubes are available in different diameters and in a wide range of materials.

In large substrate coating devices, long and heavy cathodes have to be provided. In order to support these cathodes, various support constructions have been proposed, e.g. in European Patent EP No: 1 355 343 A2 or U.S. Pat. No. 5,096,562. Cantilever type supports as well as two-end type supports are known. The entire disclosure of the foregoing references is incorporated herein by reference for all purposes.

In order to facilitate the rotation of the cathode or target, the cathode or target is supported by bearings. Usually a considerable number of bearings are arranged along the drive spindle extending from one or both sides of the cathode in order to provide sufficient and reliable support and positioning of the cathode. For example, at least two bearings are required to support the drive shaft and the cathode or target and to provide sufficient stability for the drive shaft in the radial direction and in the axial direction. However, most of the known constructions require considerable constructed space in order to fulfill the security, precision and reliability needs.

The bearings include journal and thrust bearings to support the drive shaft. For example, it is known to use single-ball bearings or double-ball bearings including an outer race, an inner race and one or two sets of balls positioned between the inner race and the outer race. The balls are circumferentially spaced relative to one another by a cage.

Above all, in most applications it is required to deposit a sufficiently homogeneous and uniform layer of coating material over the complete substrate surface. This may, however, be particularly critical in marginal areas of the surface of the substrate surface. Therefore, attempts have been made to increase the thickness of the target material at both ends of the target. Furthermore, targets having an excess length projecting over the edge of the substrate are provided.

As described above, conventional support constructions are quite complicated and require a lot of installation space, particularly in the longitudinal direction of the cathode.

### BRIEF SUMMARY OF THE INVENTION

It is an object of the present invention to provide a sputter cathode assembly and a sputter coating device having a rotatable cathode requiring reduced installation space, but without affecting precision and stability requirements. This object is achieved by providing a sputter cathode assembly and a sputter coating device having features that are subject matter described in details herein.

According to the invention, a sputter cathode assembly, particularly a magnetron sputter cathode assembly, comprises at least one bearing system for rotatably supporting a rotatable cathode or target structure. The bearing system comprises at least one combined axial and radial bearing.

The sputter cathode assembly is provided for a rotary cathode device having a rotary cathode or target structure, particularly a substantially cylindrical cathode or target.

The sputter cathode assembly comprises a particular bearing system which is arranged between a stationary housing or fixed member and the rotatable cathode or target. The fixed member may be attached to the wall of a coating chamber.

The combined axial and radial bearing is a single bearing combining an axial bearing (i.e. thrust bearing) to withstand thrust and a radial bearing (i.e. journal bearing) to withstand radial forces. The “combined” axial and radial bearing usually comprises one outer race component, one inner race component and a set of rollers, e.g. cylinders, arranged in a retainer structure. The rollers may be held in an annular cage arranged between the outer race and the inner race.

In conventional support units for magnetrons, at least two bearings spaced along the rotation axis are provided for rotatably supporting the magnetron. Because of the installation of just one bearing instead of two or more bearings the construction may be small and compact. Thus the required installation space may be reduced. Furthermore, the inventor has found out that the stability and precision of a combined axial and radial bearing in a sputter coating device are even better than the stability and precision of two or more axially spaced thrust and/or journal bearings.

When arranging compact support units according to the invention within a coating chamber, the axial length of the target could be increased because of the shorter length of the support units. Therefore, the excess length of the target exceeding the width of the substrate may be increased to result in an improved uniformity of the coating in the marginal areas of the substrate surface.

Particularly, the combined axial and radial bearing is a cross roller bearing. In the cross roller bearing, the substantially elongated cylindrical rollers are crossed at a suitable angle, for example, at a 90° angle, in an alternating fashion and enclosed between an inner race and an outer race.

The outer race may have a machined V-shaped grooved support and hold the rollers. The rollers may have, for example, a cross or “X”-configuration, which means that the angle of rotation of the cylinders define a cross or “X”. The crosses or “X”-type roller bearing provides high load-carrying capacities, can absorb great load impacts, and provides low-friction motion.

The cathode or target is rotatably supported by the cross roller bearing. The cross roller bearing carries the weight of the rotating cylindrical structure of the cathode or target irrespective of the orientation of the cathode.

Particularly, the sputter cathode assembly includes a rotatable cathode or target. The cathode generally comprises an elongated rotatable cylindrical tube having a target surface of sputter material. The cathode may be provided with an elongated magnet assembly or magnetron inside the cathode. The magnet assembly is stationary while the target rotates. Furthermore, cooling means for cooling the cathode may be provided inside the tube.

A cathode potentially supplies to the rotatable cathode from a power source. An AC or DC power supply may supply the cathode with electrical power. The bearing configuration according to the invention may be installed in AC and DC rotatable magnetrons.

In one embodiment of the invention, the sputter cathode assembly may comprise a support unit comprising at least a housing or fixed member. The fixed member or housing is rigidly connected to the coating chamber wall. The support unit may also be an end block, for example, a drive end block or a support end block.

In another embodiment of the invention, the cathode or target is connected with a drive shaft or spindle shaft. The drive shaft protrudes at one axial end or at two axial ends of the cathode. It may be driven by a drive means to rotate the cathode.

Particularly, the bearing is arranged between the drive shaft and the fixed member of the support unit. Usually the drive shaft is supported by the support unit with the bearing arranged between the stationary fixed member or housing and the drive shaft. The bearing supports the drive shaft as it rotates with the cathode. The conventional configuration of two bearings is replaced by a single bearing including a combined axial and radial bearing, such as a cross roller bearing.

In one embodiment of the invention, means for driving the drive shaft to rotate the cathode or target are provided. The cathode or target is rotated by a drive system about its longitudinal axes. The drive means are operably connected with the target structure.

The support assembly may be configured to provide for a cantilever type mounting of the rotatable cathode. The first end of a rotatable cathode is supported, while the second end is unsupported. At least one of the ends is supported by at least one combined axial and radial bearing according to the invention.

In another embodiment of the invention, the support assembly is configured to provide a two-end support type mounting of the rotatable cathode. In this embodiment, both ends of the cathode are supported by a combined axial and radial bearing. In a sputter device with a drop-in cathode that is completely inserted in particular retainer constructions within the sputter chamber, vacuum space may be saved and the width of the target may be increased.

The invention also provides a sputter coating device including a coating chamber and a sputter cathode assembly as described above. In a specific embodiment of the invention, the sputter coating device is a magnetron sputtering apparatus.

A rotatable magnetron coating device usually comprises a vacuum sputtering chamber, a rotatable target arranged within the vacuum chamber, and a drive shaft connected with the target. The drive shaft may have a cylindrical shape and extend through an opening in the vacuum chamber wall. The drive shaft may be rotated by a suitable drive assembly. A seal between the vacuum chamber and the drive spindle may be constructed as a combination of a bearing and a seal. Ferrofluidic seals are known for sealing the interior of the vacuum chamber by using a rotary vacuum feedthrough. The target is connected with the drive shaft for rotating therewith. In a conventional device, the target is supported by a plurality of bearings arranged at least along a longitudinal portion of the drive shaft.

The present invention replaces the support assembly having a plurality of bearings with the inventive support assembly having at least one combined axial and radial bearing. Due to the fact that a single bearing is sufficient to support the rotatable cathode, a cheap and space saving coating device may be provided.

The cathode or target may be supported in a horizontal, vertical or tilted orientation within the coating chamber. Whether the target is arranged and operated in a horizontal, vertical or inclined position depends on the application and on the construction of the coatings device.

With the present invention, a compact and stable support construction for rotatably supporting a cathode or target may be obtained.

### BRIEF DESCRIPTION OF THE DRAWINGS

Further features and advantages of the invention are apparent from the following description of embodiments using the enclosed drawings. The figures are shown below:

FIG. 1 is a partially sectional view of a conventional magnetron cathode assembly.

FIG. 2 is a partially sectional view of a magnetron cathode assembly according to the present invention.

FIG. 3 is a sectional side view of a vacuum chamber with various arrangements of the magnetron cathode assembly according to the present invention.

FIG. 4 is a sectional view of a conventional sputter coating device.

FIG. 5 is a sectional view of a sputter coating device according to the present invention.

FIG. 6 is a schematic illustration of a bearing construction used in conventional magnetron cathode assemblies.

FIG. 7 is a schematic illustration of a bearing construction used in a magnetron cathode assembly according to the present invention.

FIG. 8 is an illustration of a bearing used in the magnetron cathode assembly according to the invention.

### DETAILED DESCRIPTION OF THE INVENTION

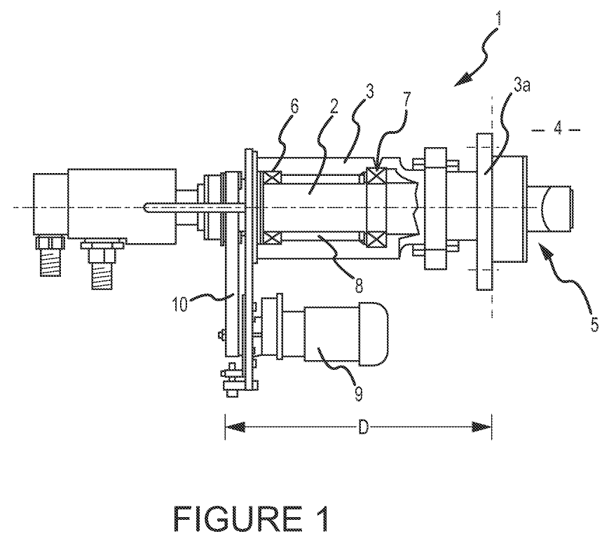

FIG. 1 illustrates a conventional magnetron cathode assembly 1. The magnetron cathode assembly 1 includes a drive shaft 2 that extends into the interior 4 of a vacuum chamber. The vacuum chamber wall is schematically indicated by a dashed line. The housing or fixed member 3 of the assembly 1 is rigidly attached to the vacuum chamber by attaching a mounting flange 3a to a wall of the vacuum chamber. A sealing is provided for sealing the interior 4 of the vacuum chamber to maintain vacuum pressure inside during the coating process.

At the end 5 extending into the interior 4 of the vacuum chamber, the drive shaft 2 comprises a mounting portion which is rigidly connected with the cathode or target so that the cathode or target may be rotated together with the drive shaft 2. The drive shaft 2 may be rotated by a drive 9. The torque of the drive 9 is transmitted to the drive shaft 2 by means of a drive belt 10, a chain or gearing (not shown).

The drive shaft 2 is rotatably supported in the housing 3 of the assembly 1 by a first conventional roller bearing 6 and a second conventional roller bearing 7. The bearings 6 and 7 are spaced apart along the axial direction of the drive shaft 2. Between the bearings 6 and 7 there may be provided a spacing member 8 in order to secure a proper spacing between the bearings 6 and 7.

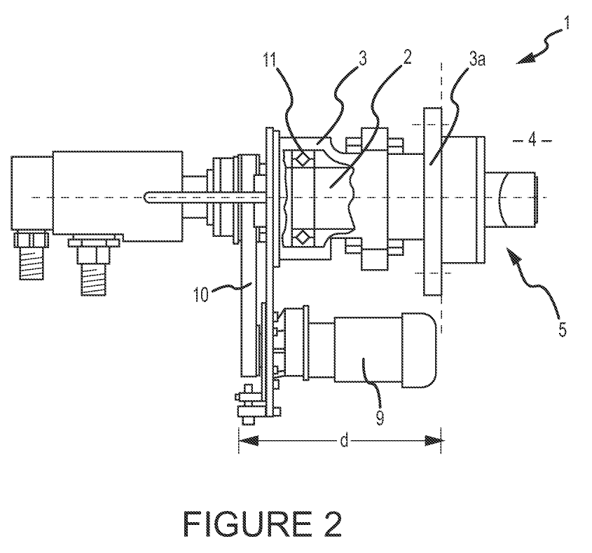

FIG. 2 illustrates a magnetron cathode assembly 1 according to the present invention, where parts corresponding to parts of the conventional cathode assembly illustrated in FIG. 1 are designated with the same reference numerals.

The magnetron cathode assembly 1 according to the present invention comprises a drive shaft 2. One end 5 of the drive shaft 2 may be connected with a cathode or target assembly in the interior space 4 of a vacuum chamber.

According to the invention, instead of using at least two conventional roller bearings spaced apart along the longitudinal axis of the drive shaft 2, a combined radial and axial bearing (i.e. a combined journal bearing and thrust bearing) 11 supports the drive shaft 2 in a housing 3 which is rigidly fixed to a chamber wall of the vacuum chamber of the coating device by a mounting flange 3a. The bearing supports the shaft 2 rotatably relative to the housing 3. In a specific embodiment of the invention, a cross roller bearing 11 is used for supporting the cathode or target structure. The specific cross roller bearing 11 is described below and illustrated in FIG. 7.

Due to the fact that a single combined radial and axial bearing 11 replaces two conventional bearings 6 and 7 or even a plurality of bearings, the longitudinal distance between the chamber wall and the drive unit 9, 10 could be considerably reduced from a distance D in the conventional assembly (see FIG. 1) to a smaller distance d in the assembly according to the invention (see FIG. 2). Thus, the required installation space could be reduced accordingly.

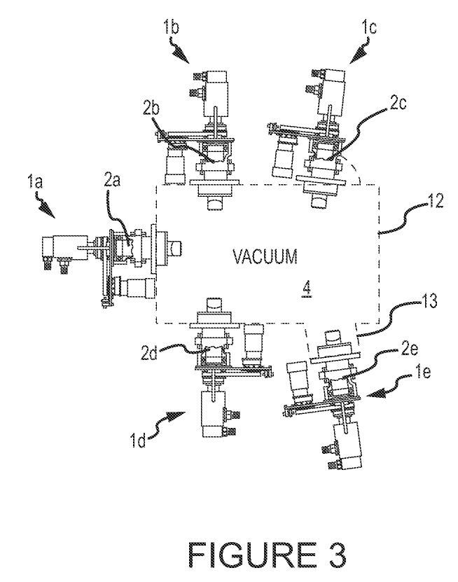

When using a cross roller bearing 11 that may resist axial forces that is in the direction of the longitudinal axis of the cylindrical cathode as well as radial forces in a magnetron sputtering device, there are various possibilities to arrange the inventive magnetron cathode assembly 1 at a vacuum chamber wall 12 as illustrated in FIG. 3. A first magnetron cathode assembly 1a is side mounted at the vacuum chamber wall 12. The longitudinal axis of the drive shaft 2a is arranged horizontally.

The magnetron sputter arrangements 1b and 1c are mounted at the top wall 12 of the vacuum chamber, where a second drive shaft 2b is arranged vertically, the longitudinal axis of a third drive shaft 2c includes an acute angle with the top wall of the vacuum chamber. The top wall is along a horizontal direction.

The magnetron sputter arrangements 1d and 1e are mounted at the bottom wall 12 of the coating chamber, where the longitudinal axis of a fourth drive shaft 2d is arranged vertically, and the longitudinal axis of a fifth drive shaft 2e includes an acute angle with the bottom wall of the vacuum chamber (i.e. with the horizontal line). For mounting the assembly 1e, a particular connecting piece 13 is provided at the vacuum chamber wall 12.

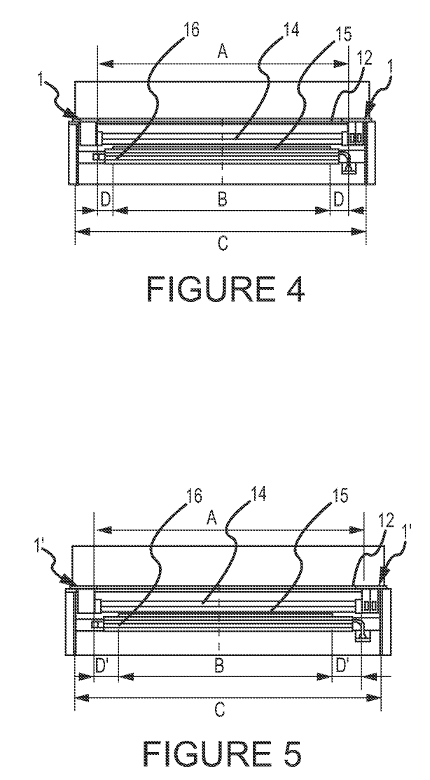

FIGS. 4 and 5 illustrate respective sectional views of a sputter coating device having a rotary cathode or target 14 of a “drop-in” type in a sectional view perpendicular to the transport direction of a substrate 15. FIG. 4 shows a conventional coating device, while FIG. 5 illustrates a coating device according to the present invention.

In FIGS. 4 and 5, a rotatable magnetron cathode or target 14 is provided within a sputter coating chamber 12 of a coating device. A substrate 15 having a defined width indicated by distance arrow B is arranged on a transport mechanism, such as rollers 16, and transported through the vacuum chamber 12 to pass the cathode or target 14 in order to be coated.

While a cantilever type mounting of the rotatable cathode is possible, in FIGS. 4 and 5 the first and second ends of the cathode 14 are supported by respective cathode support structures 1 and 1′, respectively. At least one of the cathode support structures 1 and 1′ may comprise a bearing structure. In particular, each of the cathode support structures 1 or 1′ may have at least one bearing structure on either side. While the conventional sputtering device comprises conventional bearing arrangements, the sputtering device according to the invention comprises at least one cross (“X”-) bearing device or one cross (“X”-) bearing device on either side of the cathode.

When using the magnetron cathode arrangement 1 as shown in FIG. 4, the total width of the chamber indicated as C allows an excess length D of the cathode or target 14 extending over the side edge of the substrate 15 on both sides of the substrate 15. This excess length D is limited by the construction length of the conventional magnetron sputter arrangement 1 which has to be accommodated within the coating chamber 12 in the “drop-in” type coating device.

The inventive magnetron sputter arrangements 1′ having a shorter construction length provide for an excess length D′ larger than the excess length D in a comparable coating system using conventional magnetron cathode arrangements 1. In a number of applications, however, an increase in the excess length D′ improves the quality of the coating layer, particularly near the end edges of the substrates 15.

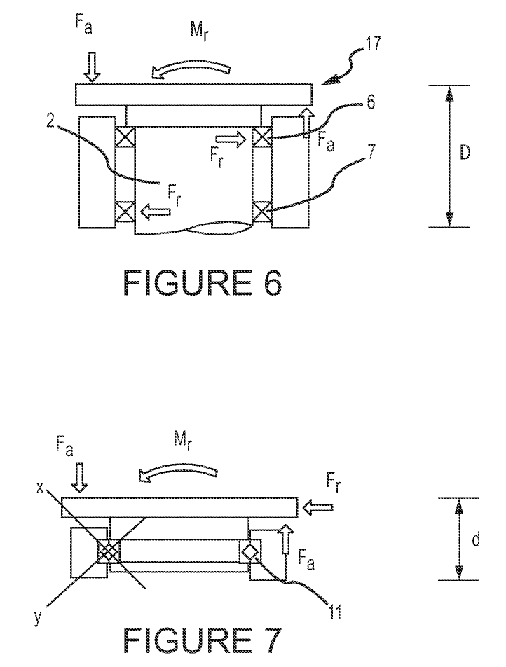

FIG. 6 illustrates a schematic view of a bearing system 17 according to the state of the art. The bearing system 17 includes two bearings 6 and 7 and a drive shaft 2 which is rotatably supported by the bearing system 17. The bearings 6 and 7 are, for example, conventional single-ball or two-ball bearings. As indicated by the arrows Fᵣ and Fₐ, the bearing system 17 may withstand radial forces Fᵣ and axial forces Fₐ. The rotation of the shaft 2 is indicated by the arrow Mᵣ. The installation length of the bearing system 17 is indicated with the arrow D.

FIG. 7 shows a bearing system having combined radial and axial bearings 11, such as a cross roller bearing which may withstand radial and axial forces. Thus, a shorter installation length indicated by arrow d may be implemented. Radial and axial forces Fᵣ and Fₐ are both absorbed by the combined radial and axial bearing 11.

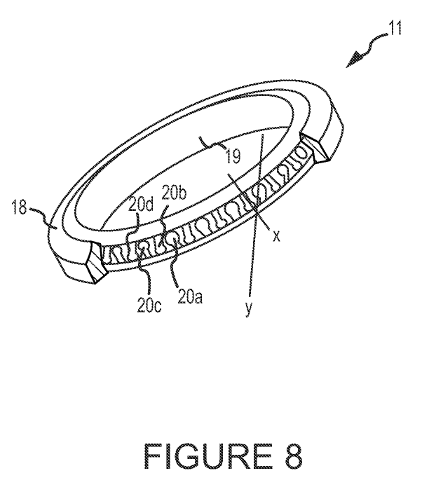

FIG. 8 illustrates a cross roller bearing 11 as an example of a combined axial and radial bearing. It comprises an outer race (outer ring) 18, an inner race (inner ring) 19 and a plurality of cylindrical rollers such as 20a, 20b, 20c, 20d arranged between the outer race 18 and the inner race 19. The rollers are generally arranged in a respective retainer, for example, spaced by spacers arranged between the rollers 20a, 20b, 20c, 20d or provided in a cage. The spacers may be made of a plastic material.

The rotational axes y of a first plurality of rollers such as 20a, 20c are arranged on a cone-shaped surface, and the rotational axes x of a second plurality of cylindrical rollers such as 20b, 20d are arranged on a second cone-shaped surface. The first and second cone-shaped surfaces include an angle, such as a 90° angle. The cylindrical rollers of the first plurality of rollers 20a, 20c are interposed between cylindrical rollers of the second plurality of rollers 20b, 20d. In other words, the rollers of the first plurality of rollers 20a, 20c and the rollers of the second plurality of rollers 20b, 20d are alternately circumferentially arranged between the outer race 18 and the inner race 19 of the bearing 11. The rollers of the first plurality of rollers and the second plurality of rollers are crossed such as at a 90° angle in an alternating fashion.

The outer race 18 has a machined V-shaped groove to support the rollers. In the embodiment of the invention, the outer race is comprised of two parts and fixed by suitable retainers (not shown). The outer race 18 and the inner race 19 function as a rail that enclose the rollers 20a, 20b, 20c, 20d.

Because of the cross-type arrangement of the rollers 20a, 20b, 20c, 20d, respectively, the bearing 11 may withstand an axial load from both sides, a radial load, torque, tilting and combinations of these loads in a single bearing. Thus, the conventional construction included two spaced bearings can be reduced to a single bearing. Furthermore, it has been recognized that combined bearings are characterized by large stiffness and a high running precision.

What is claimed is:

1. A sputter cathode assembly, comprising at least one bearing system for rotatably supporting a rotatable cathode or target structure, wherein the bearing system comprises at least one combined axial and radial bearing.

2. The sputter cathode assembly of claim 1, wherein the sputter cathode assembly comprises a magnet assembly inside the cathode.

3. The sputter cathode assembly of claim 1, wherein the combined axial and radial bearing comprises a cross roller bearing.

4. The sputter cathode assembly of claim 1, wherein the sputter cathode assembly comprises at least one rotatable cathode or target.

5. The sputter cathode assembly of claim 1, wherein the support assembly comprises a support assembly having at least a fixed member.

6. The sputter cathode assembly of claim 5, wherein the rotatable cathode or target structure is connected with a drive shaft.

7. The sputter cathode assembly of claim 6, wherein the combined axial and radial bearing is arranged between the drive shaft and the fixed member of the support assembly.

8. The sputter cathode assembly of claim 6, wherein the sputter cathode assembly is adapted to a component for driving the drive shaft to rotate the cathode or target structure.

9. The sputter cathode assembly of claim 1, wherein the sputter cathode assembly is configured to provide for a cantilever type mounting of the rotatable cathode or target structure.

10. The sputter cathode assembly of claim 1, wherein the sputter cathode assembly is configured to provide for a two-end support type mounting of the rotatable cathode or target structure.

11. A sputter coating device, comprising:
a coating chamber;
a rotatable cathode or target; and
at least one bearing system for rotatably supporting the rotatable cathode or target, wherein the bearing system comprises at least one combined axial and radial bearing.

12. The sputter coating device of claim 11, wherein the rotatable cathode or target is supported in a horizontal, in a vertical or in a tilted orientation.

13. The sputter coating device of claim 11, wherein a magnet assembly is located inside the rotatable cathode.

14. The sputter coating device of claim 11, wherein the combined axial and radial bearing comprises a cross roller bearing.

15. The sputter coating device of claim 11, further comprising a supporting assembly having at least a fixed member.

16. The sputter cathode assembly of claim 15, wherein the rotatable cathode or target is connected with a drive shaft.

17. The sputter cathode assembly of claim 16, wherein the combined axial and radial bearing is arranged between the drive shaft and the fixed member of the supporting assembly.

18. The sputter cathode assembly of claim 16, wherein the drive shaft is configured to rotate the cathode or target.

19. The sputter cathode assembly of claim 11, wherein the rotatable cathode or target is configured for a cantilever type mounting.

20. The sputter cathode assembly of claim 11, wherein the rotatable cathode or target is configured for a two-end support type mounting.
